(19) United States
(12) Patent Application Publication
(10) Pub. No.: US 2011/0175233 A1
(43) Pub. Date: Jul. 21, 2011

(54) SEMICONDUCTOR DEVICE AND METHOD FOR FABRICATING THE SAME

(76) Inventor: Akira UEKI, Osaka (JP)

(21) Appl. No.: 12/983,039

(22) Filed: Dec. 31, 2010

(30) Foreign Application Priority Data
Jan. 19, 2010 (JP) 2010-008899
Nov. 2, 2010 (JP) 2010-246320

(51) Int. Cl. H01L 23/528; H01L 21/768

(52) U.S. Cl. 257/774; 438/638; 257/E23.151; 257/E21.585

(57) ABSTRACT

A method for fabricating a semiconductor device includes the steps of: forming a mask material film on an insulating film that is formed over a semiconductor substrate and then forming a mask pattern having a first trench formation opening and a second trench formation opening from the mask material film; forming, on the mask material film, a resist pattern having a third trench formation opening that exposes the first trench formation opening and covering the second trench formation opening; forming a first trench in the insulating film using the resist pattern and the mask pattern; and forming a second trench in the insulating film using the mask pattern after removing the resist pattern.

### CROSS-REFERENCE TO RELATED APPLICATION

This application claims priority to Japanese Patent Application No. 2010-008899 filed on Jan. 19, 2010 and Japanese Patent Application No. 2010-246320 filed on Nov. 2, 2010, the disclosure of which including the specifications, the drawings, and the claims is hereby incorporated by reference in its entirety.

### BACKGROUND

The present disclosure relates to a semiconductor device and a method for fabricating the same, and more particularly to a semiconductor device having an embedded interconnect structure and a method for fabricating the same.

As semiconductor integrated circuits become finer and finer, the cross-sectional area of interconnects is being reduced, increasing the interconnect resistance. Interconnect delay occurs with the increase in interconnect resistance, and this hinders enhancement in the performance of semiconductor devices. In recent years, therefore, some efforts for reducing the interconnect resistance have been made.

A method for fabricating a semiconductor device shown in Japanese Patent Publication No. H07-106324 will be described with reference to FIGS. 10A-10D, which are cross-sectional views showing the conventional fabrication method.

As shown in FIG. 10A, a first trench 3A is formed in an interlayer insulating film 2, which is deposited on a semiconductor substrate 1, by lithography and dry etching. The depth of the first trench 3A is referred to as a first interconnect depth (first interconnect height) T1 (see FIG. 10B).

As shown in FIG. 10B, a resist 4 is applied to the top surface of the interlayer insulating film 2 and then patterned by lithography. Using the patterned resist 4, the interlayer insulating film 2 is dry-etched, to form a second trench 3B having a second interconnect height T2 different from the first interconnect height T1.

As shown in FIG. 10C, after removal of the resist 4, the first trench 3A and the second trench 3B are filled with a metal film 5 by sputtering and plating.

As shown in FIG. 10D, an excess portion of the metal film 5 is removed by polishing, to allow the metal film 5 to remain only in the trenches. In this way, interconnects 6A and 6B having different interconnect heights T1 and T2 can be formed.

### SUMMARY

The conventional technique described above has the following problems. The first problem is that the number of process steps increases. In the conventional technique, the lithography process and the dry etching process are necessary a plurality of times for formation of interconnects as shown in FIGS. 10A and 10B. Increase in the number of process steps may cause increase in fabrication cost and decrease in yield.

The second problem is that it is necessary to secure a resist film thickness required for formation of a deep trench as shown in FIG. 10B. While the resist must be thick to form a deep trench, a thick resist may possibly affect patterning of the resist by lithography, like degrading the patterning precision and causing collapse of the resist.

The third problem is that damage to the interlayer insulating film increases. In the steps shown in FIG. 10A and 10B, after formation of trenches by dry etching, it is necessary to remove the resist by ashing and clean off polymer residues. When a film low in dielectric constant is used as the interlayer insulating film, damage to the interlayer insulating film in the above steps may possibly increase the dielectric constant.

In a semiconductor device of an example embodiment of the present invention, the interconnect resistance can be reduced without increasing the fabrication cost and decreasing the yield.

It should be noted that, according to the present invention, it is not necessarily required to solve all of the problems described above, but solving only one of them is sufficient.

The method for fabricating a semiconductor device of an example of the present invention includes the steps of: forming an insulating film over a semiconductor substrate; forming a mask material film on the insulating film and then forming a mask pattern having a first trench formation opening and a second trench formation opening from the mask material film; forming, on the mask material film, a resist pattern having a third trench formation opening that exposes the first trench formation opening and covering the second trench formation opening; forming a first trench in a position in the insulating film coinciding with the third trench formation opening using the resist pattern and the mask pattern; and after removing the resist pattern, forming a second trench in a position in the insulating film coinciding with the second trench formation opening using the mask pattern.

According to the above method, in which the third trench formation opening exposes the first trench formation opening, the first trench can be formed in a self-aligned manner even if the resist pattern is misaligned. Thus, low-resistance interconnects can be formed minutely. Also, since the first and second trenches different in height can be formed using general lithography and dry etching processes, interconnects different in height can be formed without increasing the number of steps. Thus, a semiconductor device having a desired interconnect structure can be fabricated without increasing the fabrication cost and the time required for fabrication.

In the step of forming a second trench, the first trench can be further dug to be deeper than the second trench.

The widths of the first trench and the second trench may be substantially the same. The wording “substantially the same” is used herein to include the case that the widths of the first trench and the second trench are not precisely the same due to variations in formation conditions, etc. although they are designed to be the same.

The insulating film formed on the semiconductor substrate may include a lower insulating film and an upper insulating film formed on the lower insulating film, and the method may further include the step of removing the upper insulating film after formation of the second trench.

In the above case, occurrence of damage can be suppressed even if a low-k film is used as the lower insulating film, for example.

The method for fabricating a semiconductor device of another example of the present invention includes the steps of: forming an insulating film over a semiconductor substrate; forming a mask material film on the insulating film and then forming a mask pattern having a first trench formation opening and a second trench formation opening from the mask material film; forming, on the mask material film, a resist pattern having a third trench formation opening that exposes the first trench formation opening and a contact hole formation opening that exposes part of the second trench formation opening; forming a first trench in a position in the insulating film coinciding with the third trench formation opening, and also forming a contact hole in a position in the insulating film coinciding with the contact hole formation opening, using the resist pattern and the mask pattern; and after removing the resist pattern, forming a second trench having a bottom at which the contact hole is open in a position in the insulating film coinciding with the second trench formation opening using the mask pattern.

According to the above method, the first contact and the first trench can be formed without largely increasing the number of steps.

The semiconductor device of an example of the present invention includes: a first insulating film formed over a semiconductor substrate; a first interconnect formed in the first insulating film; a second interconnect formed in the first insulating film, the second interconnect being larger in height than the first interconnect; and a contact formed in the first insulating film to be connected to the first interconnect, wherein the first interconnect, the second interconnect, and the contact are each comprised of a conductive barrier film and a metal film formed on the barrier film, and no barrier film is formed at a boundary between the first interconnect and the contact.

With the above configuration, desired interconnects can be formed using the dual damascene process without increasing the number of steps.

The semiconductor device of another example of the present invention includes: a first insulating film formed over a semiconductor substrate; a first interconnect formed in the first insulating film; a second interconnect formed in the first insulating film, the second interconnect being larger in height than the first interconnect; a second insulating film formed between the semiconductor substrate and the first insulating film; and a lower interconnect formed in the second insulating film, wherein the second interconnect is directly connected to the lower interconnect.

With the above configuration, also, desired interconnects can be formed using the dual damascene process without increasing the number of steps. Therefore, the semiconductor device can be fabricated with high yield without increasing the fabrication cost.

As described above, according to the method for fabricating a semiconductor device of an example of the present invention, in which the third trench formation opening exposes the first trench formation opening, the first trench can be formed in a self-aligned manner even if the resist pattern is misaligned. Thus, low-resistance interconnects can be formed minutely.

Also, since large increase in the number of steps is unnecessary in the example method, compared with the general dual damascene process, the fabrication cost and the time required for fabrication can be suppressed from increasing.

### BRIEF DESCRIPTION OF THE DRAWINGS

FIGS. 1A-1C are cross-sectional views showing a method for fabricating a semiconductor device of an example embodiment of the present invention.

FIGS. 2A-2C are cross-sectional views showing the method for fabricating a semiconductor device of the example embodiment of the present invention.

FIG. 3A-3C are cross-sectional views showing the method for fabricating a semiconductor device of the example embodiment of the present invention.

FIG. 4 shows a plan view (upper view) and cross-sectional view (lower view) of the semiconductor device at the step shown in FIG. 2B.

FIG. 5 is a cross-sectional view of the semiconductor device of the example embodiment of the present invention.

FIG. 6A-6C are cross-sectional views showing a method for fabricating a semiconductor device of a variation of the example embodiment of the present invention.

FIG. 7A-7C are cross-sectional views showing the method for fabricating a semiconductor device of the variation of the example embodiment of the present invention.

FIG. 8A-8C are cross-sectional views showing the method for fabricating a semiconductor device of the variation of the example embodiment of the present invention.

FIG. 9 is a cross-sectional view of the semiconductor device of the variation of the example embodiment of the present invention.

FIG. 10A-10D are cross-sectional views showing a conventional method for fabricating a semiconductor device.

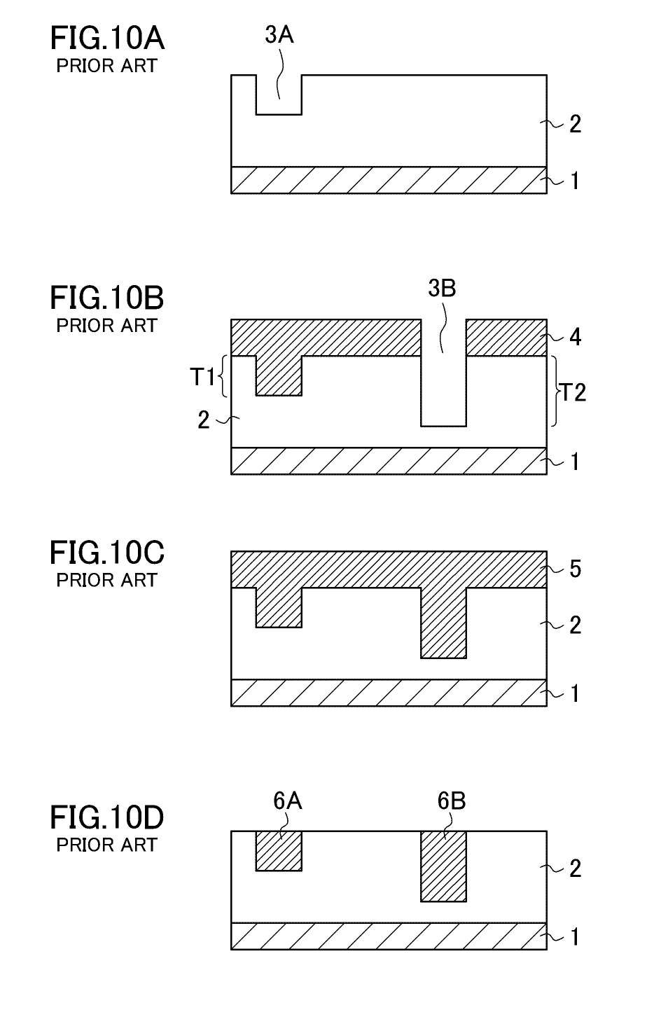

FIG. 11A is a plan view schematically showing an example of application of the semiconductor device of the example embodiment to a system LSI chip, and FIG. 11B is a cross-sectional view schematically showing an interconnect structure in a signal processing section and digital processing section of the system LSI chip.

### DETAILED DESCRIPTION

An embodiment of the present invention will be described hereinafter with reference to the drawings. It should be noted that the drawings and the shapes, materials, sizes, etc. of individual components to be described hereinafter merely represent desirable examples and do not limit the scope of the invention. It should also be noted that changes from the details to follow can be made as appropriate without departing from the spirit of the invention. The details to be described in the embodiment and its variation can be combined as appropriate as far as no contradiction arises.

-Method for Fabricating Semiconductor Device of Example Embodiment-

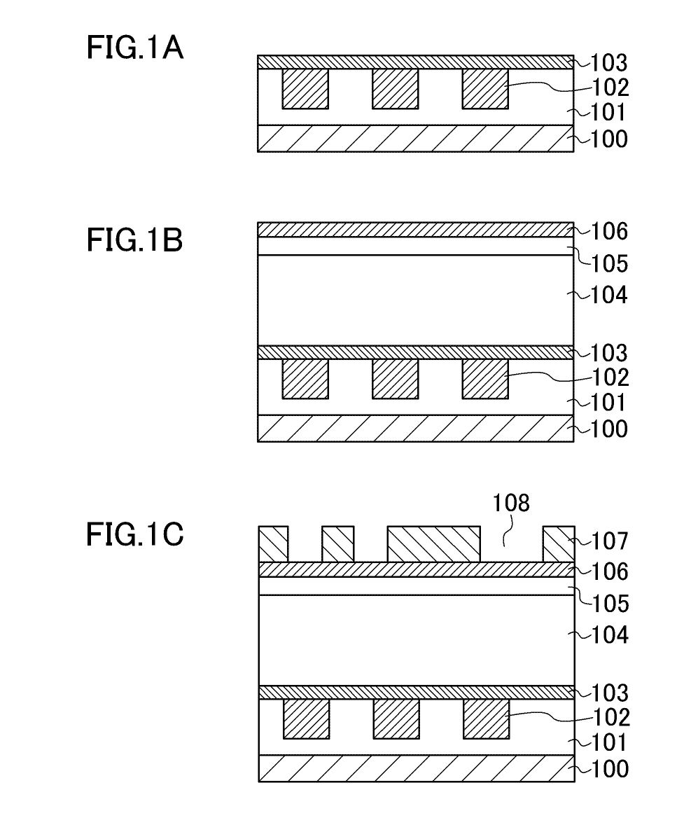

A method for fabricating a semiconductor device of an example embodiment of the present invention will be described with reference to the relevant drawings. FIGS. 1A-1C, 2A-2C, and 3A-3C are cross-sectional views showing the fabrication method of the example embodiment.

First, as shown in FIG. 1A, a protective film 103 having a thickness of about 50 nm, for example, is formed on an interlayer insulating film 101, which is formed on a semiconductor substrate 100 and has metal interconnects (lower interconnects) 102 made of copper (Cu), etc. embedded therein, for protection of the metal interconnects 102. As the protective film 103, silicon carbide (SiC), etc. may be deposited by chemical vapor deposition (CVD), for example.

As shown in FIG. 1B, an insulating film (lower insulating film) 104, an insulating film (upper insulating film) 105, and a thin film (mask material film) 106 are formed sequentially on the protective film 103. As the insulating film 104, a film made of a low dielectric constant material is used for reducing the inter-interconnect capacitance. For example, a porous low-k film having a dielectric constant (k value) of about 3.0 may be used. The low dielectric constant material as used herein refers to a material lower in dielectric constant than a silicon oxide film.

The insulating film 105 is formed to protect the insulating film 104 from being damaged due to etching, ashing, etc. A tetraethyl orthosilicate (TEOS) film, for example, may be used as the insulating film 105.

The thin film 106, formed as a hard mask for trench formation, is made of a material resistant to etching. In other words, the thin film 106 is made of a material having etching selectivity against at least the insulating films 104 and 105. Examples of such a material include titanium nitride (TiN), SiC, etc. deposited by a known method. Otherwise, Ti, tantalum (Ta), tantalum nitride (TaN), etc. may be used. The thickness of the thin film 106 is preferably several nanometers to about 50 nm. In this step, formation of the insulating film 105 may be omitted if damage to the insulating film 104 due to etching, ashing, etc. is not especially obtrusive.

As shown in FIG. 1C, a resist film 107 is formed on the thin film 106 and then subjected to lithography, to form a resist pattern 108 for formation of trenches.

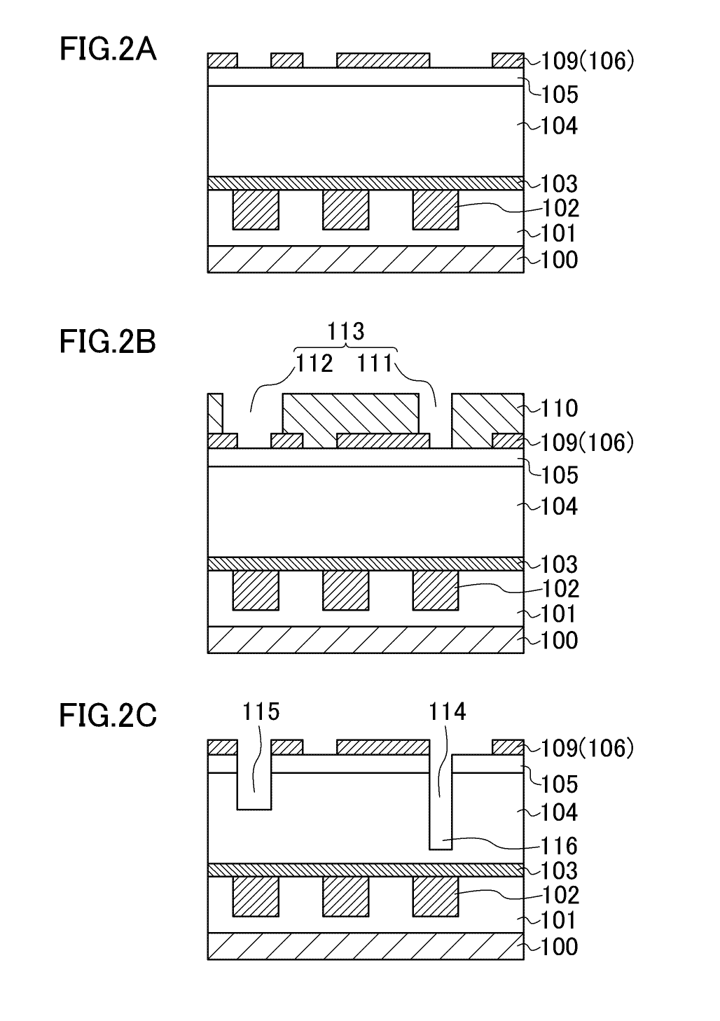

As shown in FIG. 2A, mainly the thin film 106 is etched using the resist pattern 108, to form a mask pattern 109 for trench formation.

As shown in FIG. 2B, a resist film 110 is formed on the insulating film 105 and the mask pattern 109 and then subjected to lithography, to form a resist pattern 113 having an opening 111 for formation of a contact hole (via hole) and an opening 112 for formation of a trench.

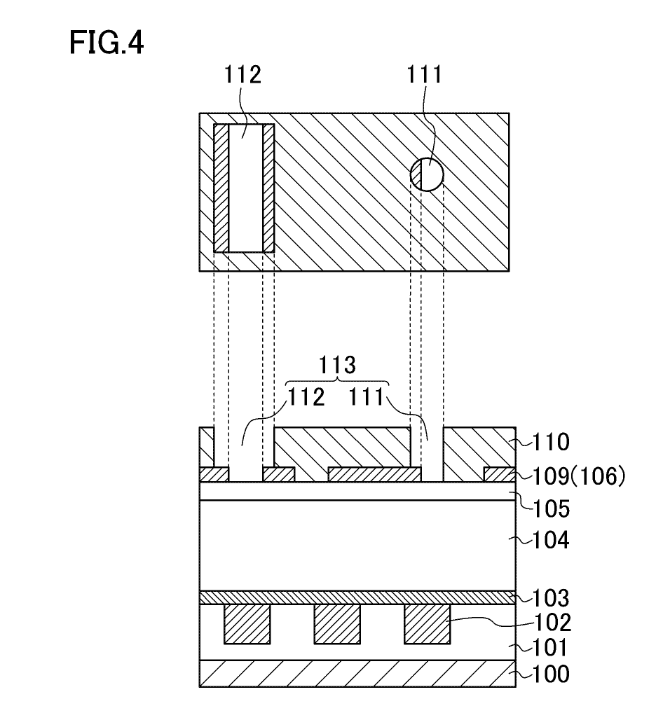

FIG. 4 shows a plan view (upper view) as viewed from above the semiconductor substrate 100, and a cross-sectional view (lower view), of the semiconductor device at the stage of this step.

As shown in FIG. 4, the trench formation opening 112 is formed to expose a trench formation opening of the mask pattern 109, and the contact hole opening 111 is formed to expose part of an opening of the mask pattern 109. As shown in FIG. 4, some openings of the mask pattern 109 overlap openings of the resist pattern 113 while others do not. In other words, some openings of the mask pattern 109 entirely coincide with openings of the resist pattern 113, some other openings partly coincide with openings of the resist pattern 113, and the remaining openings do not coincide with openings of the resist pattern 113 at all.

In the above lithography process, a mask (reticle) having openings for formation of both the contact hole formation opening 111 and the trench formation opening 112 of the resist pattern 113 may be used, or separate masks (reticles) having the respective openings may be used.

Subsequently, as shown in FIG. 2C, the insulating films 104 and 105 are etched using the resist pattern 113 and the mask pattern 109, to form a contact hole 114 and a trench 115. The etching is performed under the condition that the etching rate of the insulating films 104 and 105 is higher than that of the thin film 106. Specifically, a gas containing C and F such as CF₄ and CHF₃ is used, and the gas flow ratio, the substrate bias, the pressure, etc. are adjusted appropriately. In this etching, trenches can be formed in a self-aligned manner, like the trench 115, when openings of the resist pattern 113 (resist film 110) are wider than their coinciding openings of the mask pattern 109 (thin film 106). Also, contact holes can be formed in a self-aligned manner, like the contact hole 114, along the corresponding opening edges of the mask pattern 109.

The above etching is performed by adjusting the etching conditions such as the etching gas species, the pressure, the electric power, etc. so that the etching rate is higher for contact holes than for trenches, by use of the fact that the area of the insulating film exposed in the contact hole formation opening 111 is different from that exposed in the trench formation opening 112 as shown in FIG. 4. As a result, as shown in FIG. 2C, the contact hole 114 is deep compared with the trench 115. The resist film 110 is then removed by ashing.

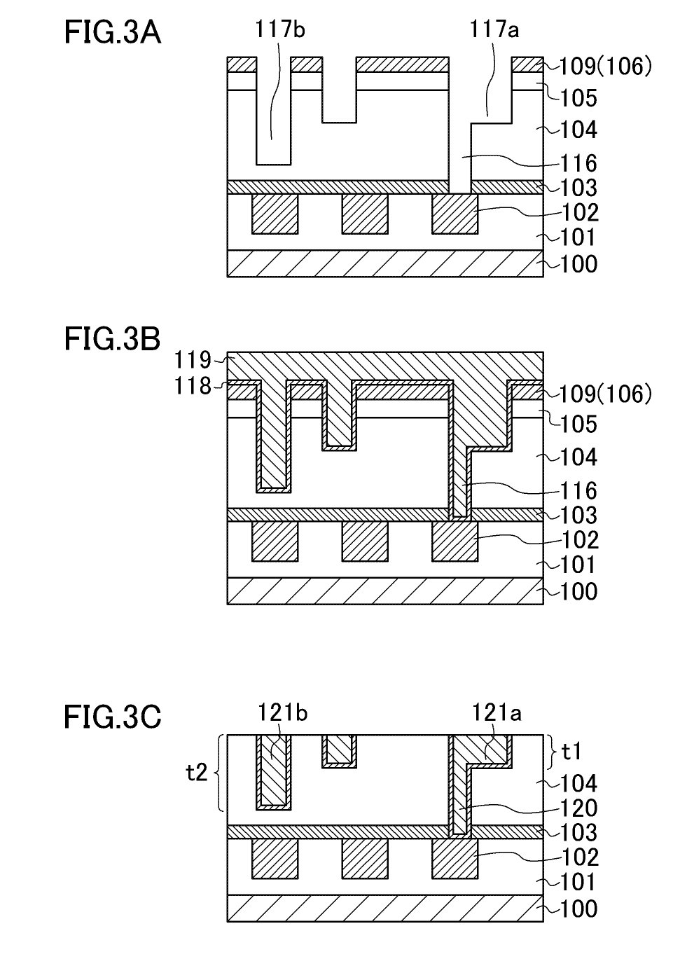

As shown in FIG. 3A, etching is performed using the mask pattern 109, under the condition that the etching rate of the insulating films 104 and 105 is higher than that of the thin film 106, until the contact hole 114 reaches the corresponding metal interconnect 102. By this etching, a trench 117a and a contact hole 116 open at the bottom of the trench 117a are formed. The trench 115 is further deepened to become a trench 117b deeper than the trench 117a. A portion of the inner wall of the contact hole 116 is flush with a portion of the inner wall of the trench 117a at a position coinciding with an edge of the corresponding opening of the mask pattern 109.

While the trench 117a is formed by etching the insulating films 104 and 105 only once (step of FIG. 3A), the trench 117b is formed by etching the films twice (step of FIG. 2C and step of FIG. 3A). Therefore, the trench 117b is deeper than the trench 117a. The width of the trench 117b is substantially the same as the width of a trench adjacent to the trench 117b on the right, for example (see FIG. 3A).

As shown in FIG. 3B, a barrier film 118 having a thickness of about 30 nm, for example, is formed on the top surface of the thin film 106 and on the inner surfaces of the contact hole 116 and the trenches 117a and 117b by sputtering, etc.

Subsequently, a metal film 119 is formed on the insulating film 104 via the barrier film 118 by plating, etc. to fill the trenches 117a and 117b and the contact hole 116 with the metal film 119. As the material of the barrier film 118, TiN, Ta, etc. may be used, and as the material of the metal film 119, Cu, aluminum (Al), tungsten (W), or any alloy of these materials may be used.

As shown in FIG. 3C, the thin film 106, the insulating film 105, and the portions of the metal film 119 and the barrier film 118 formed outside the trenches such as the trenches 117a and 117b are removed by chemical mechanical polishing (CMP), etc. Thus, an interconnect 121a having a height t1 and a contact 120 are respectively formed in the trench 117a and the contact hole 116, and an interconnect 121b having a height t2 is formed in the trench 117b.

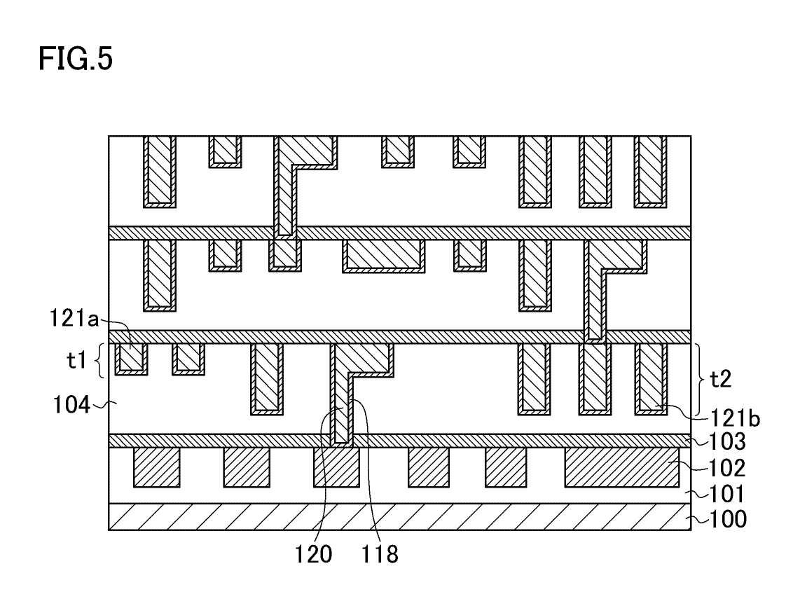

By repeating steps similar to those shown in FIG. 1A through 3C, a multilayer interconnect structure as shown in FIG. 5, for example, can be formed.

-Configuration of Semiconductor Device of Example Embodiment-

FIG. 5 is a cross-sectional view of the semiconductor device of the example embodiment of the present invention fabricated by the method described above. As shown in FIG. 5, the semiconductor device of this embodiment has a plurality of interconnect layers each having embedded interconnects made of Cu, etc.

Specifically, the semiconductor device of this embodiment includes: the semiconductor substrate 100; the metal interconnects 102 made of Cu, etc. embedded in the interlayer insulating film 101 formed on the semiconductor substrate 100; the protective film 103 formed on the metal interconnects 102 and the interlayer insulating film 101; the insulating film 104 formed on the interlayer insulating film 101 via the protective film 103; the interconnects 121a and 121b made of metal embedded in the insulating film 104; and the contact 120 embedded in the insulating film 104 for electrically connecting the corresponding interconnect 121a to the corresponding metal interconnect 102. The height t2 of the interconnects 121b is larger than the height t1 of the interconnects 121a. None of the interconnects 121b is connected to a contact that is connected to a metal interconnect 102.

The interconnects 121a and 121b are each comprised of the barrier film 118 covering the inner surfaces of the trenches and the metal film 119 formed on the barrier film 118 to fill the trenches therewith. The contact 120 is comprised of the barrier film 118 covering the inner surface of the contact hole and the metal film 119 formed on the barrier film 118 to fill the contact hole therewith. Since the contact 120 and the interconnects 121a and 121b are formed using the dual damascene process as described above, the barrier film 118 is not formed at the boundary between the contact and the interconnect connected to the contact.

The interconnects 121a and the interconnects 121b different in height may have approximately the same width, or may have different widths from each other. If having different widths, the interconnects 121a and 121b can be given different heights by etching the insulating film 104 under the condition that the etching rate varies with the trench width. However, the interconnects 121a and 121b that have the same width and different heights cannot be formed by such a method, but can only be formed using the method of this embodiment. Thus, according to the method of this embodiment, the interconnect height can be changed appropriately even if it becomes necessary to place narrowest interconnects in the smallest space. This indicates that greater merits will be obtained from the interconnect formation method of this embodiment as semiconductor devices become finer.

The diameter of the contact 120 is made smaller than the width of the interconnects 121b having a large height and the width of the interconnects 121a having a small height in case of occurrence of misalignment of the contact.

-Function/Advantage of Semiconductor Device and Its Fabrication Method-

According to the method for fabricating a semiconductor device described above, in the steps of FIGS. 2B and 2C, etching is performed under the condition that the thin film is hard to etch even when the trench formation opening 112 of the resist pattern 113 is wider than the corresponding trench formation opening of the mask pattern 109. This permits formation of the trench 115 having the width of the opening of the mask pattern 109. Thus, in formation of the resist pattern 113, a large margin can be secured for misalignment against the mask pattern 109. Accordingly, by employing the fabrication method of this embodiment, the semiconductor device with minute placement of the interconnects 121a and 121b as shown in FIG. 5 can be implemented.

According to the fabrication method of this embodiment, interconnects different in height can be formed using the lithography process and the dry etching process in the conventional dual damascene process. This permits fabrication of a semiconductor device without increasing the number of steps compared with the general dual damascene process. Thus, a semiconductor device having a desired interconnect structure can be implemented without increasing the fabrication cost and the time required for the fabrication process.

According to the fabrication method of this embodiment, two-stage etching is performed for formation of deep trenches. This eliminates the necessity of particularly increasing the thicknesses of the thin film 106 and the resist film 110 used for etching masks, and thus can prevent the patterning precision from decreasing during the lithography. Note that since the thin film 106 is made of a material excellent in etching resistance, such as SiC and TiN, compared with the resist film 110, the film scarcely causes a problem due to its wearing even though being used as the mask in the step of FIG. 2C and the step of FIG. 3A.

When the insulating film 105 higher in dielectric constant than the insulating film 104 is formed on the insulating film 104 in the interconnect formation process, the top surface of the insulating film 104 is prevented from being exposed in the ashing and cleaning process for removal of the resist film 110. Thus, damage to the insulating film 104 serving as the interlayer insulating film can be reduced.

-Application to Device-

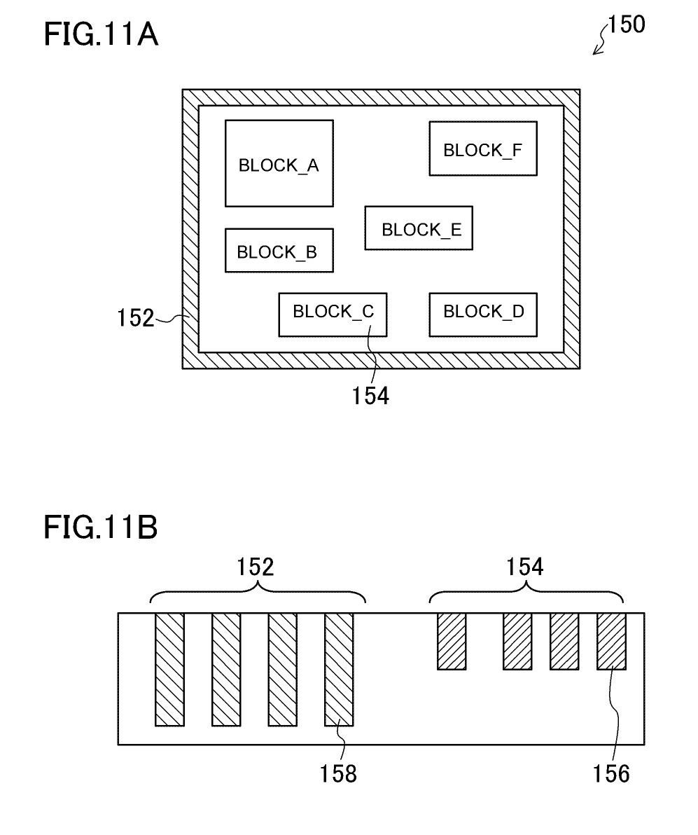

An example of actual application of the method for fabricating a semiconductor device described above to a system LSI will be described. FIG. 11A is a schematic plan view of an example of application of the configuration of the semiconductor device of this embodiment to a system LSI chip, and FIG. 11B is a schematic cross-sectional view of interconnect structures of a signal processing section and digital processing section of the system LSI chip.

As shown in FIG. 11A, a system LSI chip 150 has a signal input/output section (I/O 152) on the periphery of the chip and several digital processing sections (logic circuits 154), e.g., BLOCK_A to F, on the inner portion of the chip.

The logic circuits 154 on the system LSI chip 150 are high-speed driven with a low voltage (2 V or less) for reducing power consumption. In such logic circuits 154, shallow interconnects 156 are used for reducing the inter-interconnect capacitance and the inter-layer capacitance.

On the contrary, in the I/O 152, in particular, control of a voltage higher than that in the logic circuits 154, such as 3.3 V and 5 V, is necessary for exchange of electric signals with the outside of the chip. Therefore, having a large current flowing therein, the I/O 152 needs interconnects large in cross section enough to allow flow of such a current. Accordingly, in general, the width of the interconnects in the I/O 152 has been increased compared with that in the logic circuits 154, to secure the cross section of the interconnects.

According to the method for fabricating a semiconductor device of this embodiment, as shown in FIG. 11B, it is possible to form the shallow interconnects 156 in regions such as the logic circuits 154 subjected to high-speed, low-voltage driving, simultaneously with formation of deep interconnects 158 in interconnect regions such as the I/O 152 where a large current flows. In the I/O 152, where the deep interconnects 158 are formed, a cross section equivalent to that obtained by increasing the width of the interconnects can be secured.

Accordingly, by using the configuration of the semiconductor device and the method for fabricating the same of this embodiment, the area occupied by the I/O 152 can be reduced, and thus the chip size can be reduced, compared with the case where the interconnects in the I/O 152 are made wider than the interconnects in high-speed, low-voltage driven regions such as the logic circuits 154 while being the same in depth as the latter. Note that the interconnects in all the blocks BLOCK_A to F as the digital processing sections (logic circuits 154) are not necessarily formed simultaneously with the interconnects in the I/O section, but the interconnects in at least one of the plurality of digital processing sections may be formed simultaneously with the interconnects in the I/O section.

-Variation of Semiconductor Device and Its Fabrication Method-

A variation of the method for fabricating a semiconductor device will be described with reference to the relevant drawings.

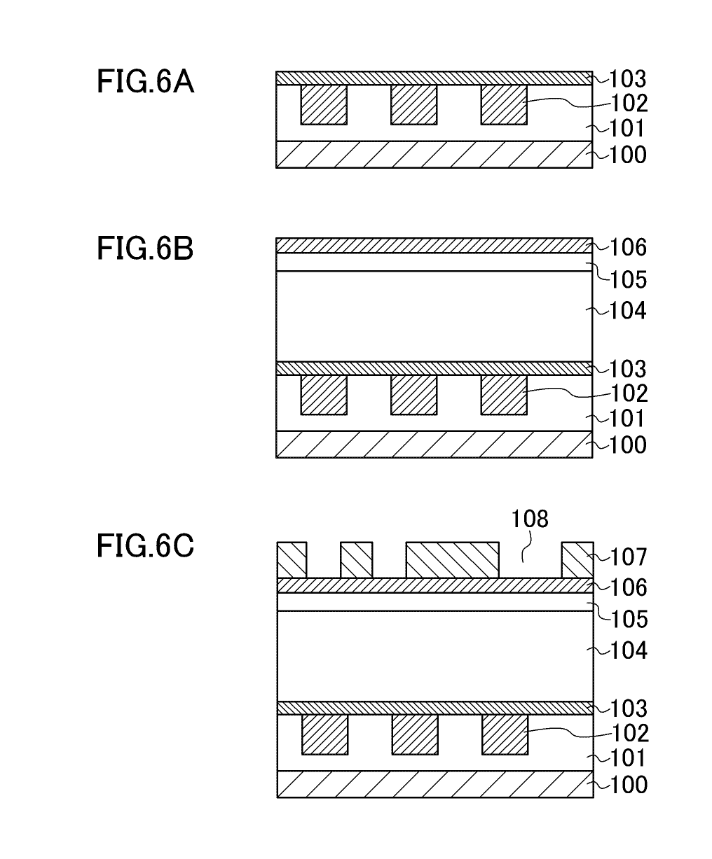

FIGS. 6A-6C, 7A-7C, and 8A-8C are cross-sectional views showing a method for fabricating a semiconductor device of a variation of the example embodiment. In this variation of the fabrication method, the etching conditions are changed from those in the step of FIG. 2C in the fabrication method described above.

As shown in FIG. 6A, a protective film 103 having a thickness of about 50 nm, for example, is formed on an interlayer insulating film 101, which is formed on a semiconductor substrate 100 and has metal interconnects 102 made of Cu, etc. embedded therein, for protection of the metal interconnects 102. As the protective film 103, SiC, etc. may be deposited by CVD, etc., for example.

As shown in FIG. 6B, an insulating film 104, an insulating film 105, and a thin film 106 are formed sequentially on the protective film 103. As the insulating film 104, a film made of a low dielectric constant material is used for reducing the inter-interconnect capacitance. For example, a porous low-k film having a k value of about 3.0 may be used.

The thin film 106, formed as a hard mask for trench formation, is made of a material resistant to etching. That is, the thin film 106 is made of a material having etching selectivity against at least the insulating films 104 and 105. Examples of such a material include, but are not limited to, TiN, SiC, etc. deposited by a known method. The thickness of the thin film 106 is preferably several nanometers to about 50 nm. In this step, formation of the insulating film 105 may be omitted if damage to the insulating film 104 due to etching, ashing, etc. is not of particular concern.

As shown in FIG. 6C, a resist film 107 is formed on the thin film 106 and then subjected to lithography, to form a resist pattern 108 for formation of trenches.

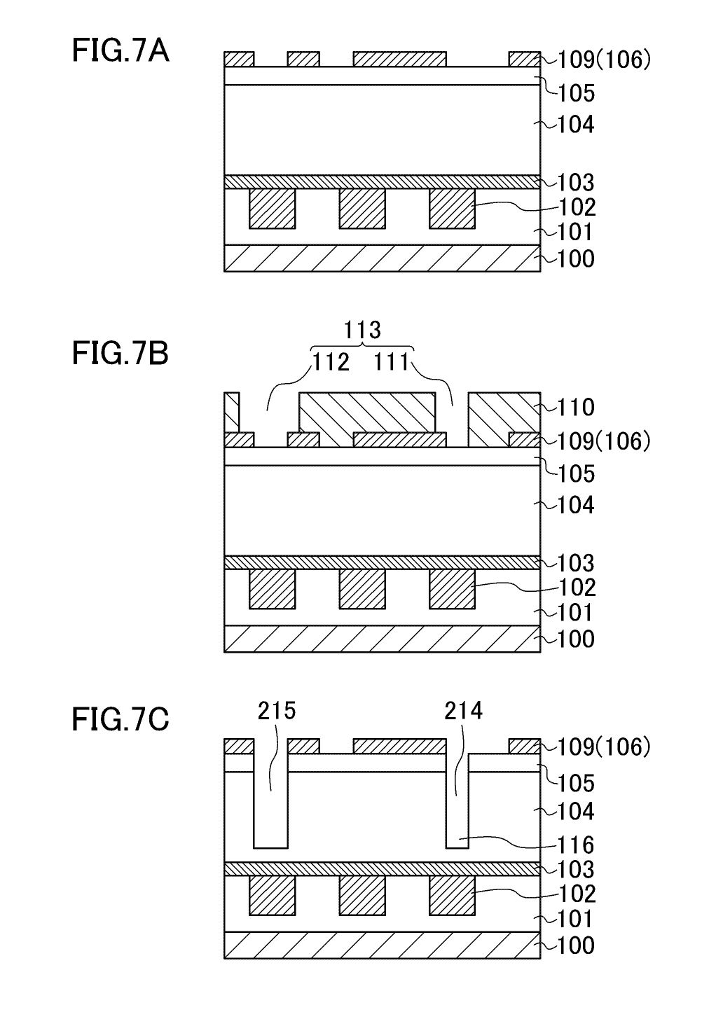

As shown in FIG. 7A, mainly the thin film 106 is etched using the resist pattern 108, to form a mask pattern 109 for trench formation.

As shown in FIG. 7B, a resist film 110 is formed on the insulating film 105 and the mask pattern 109 and then subjected to lithography, to form a resist pattern 113 having a contact hole formation opening 111 and a trench formation opening 112. The steps up to this step are the same as the steps described above with reference to FIGS. 1A through 2B.

Subsequently, as shown in FIG. 7C, the insulating films 104 and 105 are etched using the resist pattern 113 and the mask pattern 109, to form a contact hole 214 and a trench 215. The etching is performed under the condition that the etching rate of the insulating films 104 and 105 is high compared with that of the thin film 106. In this etching, trenches can be formed in a self-aligned manner, like the trench 215, when the width of openings of the resist pattern 113 (resist film 110) is equal to or larger than that of their coinciding openings of the mask pattern 109 (thin film 109). Also, contact holes can be formed in a self-aligned manner, like the contact hole 214, along the corresponding opening edges of the mask pattern 109.

Unlike the etching shown in FIG. 2C, the etching in this step is performed under the condition that the etching rates for trenches and for contact holes are approximately the same. Specifically, a gas containing C and F such as CF₄ and CHF₃ is used, and the gas flow ratio, the substrate bias, the pressure, etc. are adjusted appropriately. Thus, the trench 215 and the contact hole 214 have approximately the same depth. The resist film 110 is then removed by ashing.

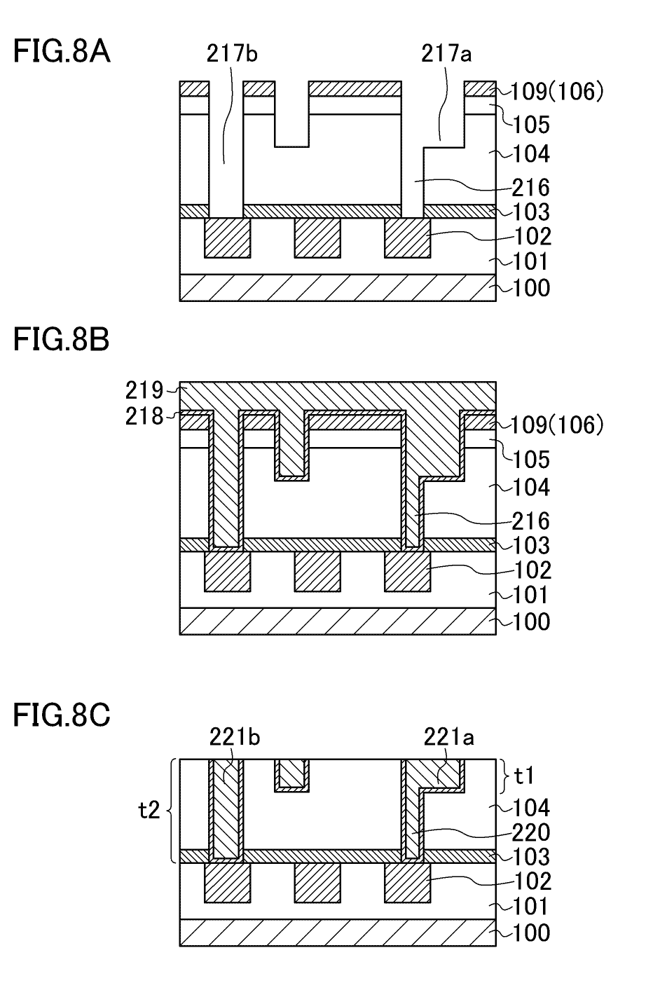

As shown in FIG. 8A, etching is performed using the mask pattern 109, under the condition that the etching rate of the insulating films 104 and 105 is higher than that of the thin film 106, until the trench 215 and the contact hole 214 reach the corresponding metal interconnects 102, thereby to form a trench 217b and a contact hole 216, respectively. A trench 217a is also formed by this etching.

While the trench 217a is formed by etching the insulating films 104 and 105 only once (in the step of FIG. 8A), the trench 217b is formed by etching the films twice (in the step of FIG. 7C and the step of FIG. 8A). Therefore, the trench 217b is deeper than the trench 217a. The top surfaces of the corresponding metal interconnects 102 are exposed in the contact hole 216 and the trench 217b.

As shown in FIG. 8B, a barrier film 218 having a thickness of about 30 nm, for example, is formed on the top surface of the thin film 106 and on the inner surfaces of the contact hole 216 and the trenches 217a and 217b by sputtering, etc. Subsequently, a metal film 219 is formed on the insulating film 104 via the barrier film 218 by plating, etc. As the material of the barrier film 218, TiN, Ta, etc. may be used, and as the material of the metal film 219, Cu, Al, W, or any alloy of these materials may be used.

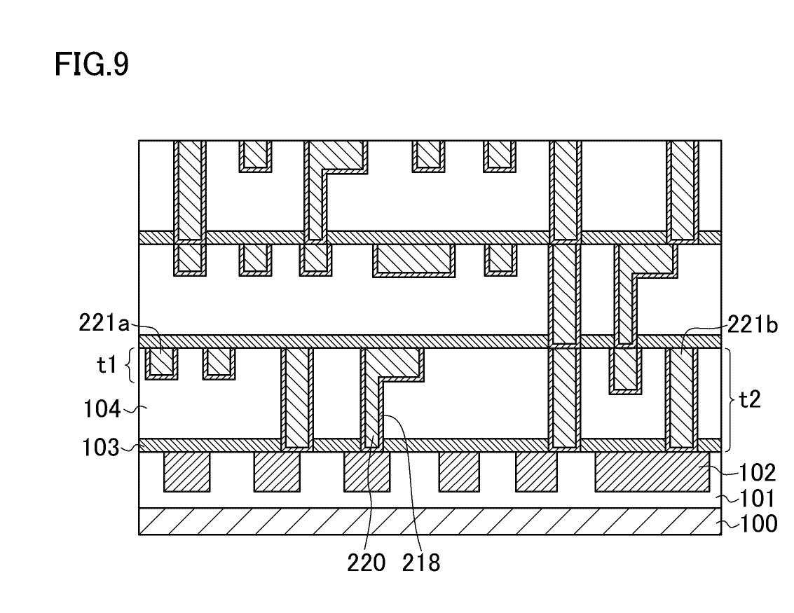

As shown in FIG. 8C, the thin film 106, the insulating film 105, and the portions of the metal film 219 and the barrier film 218 formed outside the trenches such as the trenches 217a and 217b are removed. Thus, an interconnect 221a having a height t1 and a contact 220 are respectively formed in the trench 217a and the contact hole 216, and an interconnect 221b having a height t2 larger than t1 is formed in the trench 217b (see FIG. 9). In the method of this variation, the interconnect 221b and the contact 220 are directly connected to the corresponding metal interconnects 102.

By repeating steps similar to those shown in FIG. 6A through 8C, a multilayer interconnect structure as shown in FIG. 9, for example, can be formed.

FIG. 9 is a cross-sectional view of the semiconductor device of the variation of the example embodiment of the present invention fabricated by the method described above. As shown in FIG. 9, the semiconductor device of this variation has a plurality of interconnect layers each having embedded interconnects made of Cu, etc.

Specifically, the semiconductor device of this variation includes: the semiconductor substrate 100; the metal interconnects 102 made of Cu, etc. embedded in the interlayer insulating film 101 formed on the semiconductor substrate 100; the protective film 103 formed on the metal interconnects 102 and the interlayer insulating film 101; the insulating film 104 formed on the interlayer insulating film 101 via the protective film 103; the interconnects 221a and 221b made of metal embedded in the insulating film 104; and the contact 220 embedded in the insulating film 104 for electrically connecting the corresponding interconnect 221a to the corresponding metal interconnect 102. The height t2 of the interconnects 221b is larger than the height t1 of the interconnects 221a. The interconnects 221b extend through the protective film 103 to be directly connected to the top surfaces of the corresponding metal interconnects 102.

The interconnects 221a and 221b are each comprised of the barrier film 218 covering the inner surfaces of the trenches and the metal film 219 formed on the barrier film 218 to fill the trenches therewith. The contact 220 is comprised of the barrier film 218 covering the inner surface of the contact hole and the metal film 219 formed on the barrier film 218 to fill the contact hole therewith.

The interconnects 221a and the interconnects 221b different in height may have approximately the same width, or may have different widths from each other. The diameter of the contact 220 is smaller than the width of the interconnects 221b having a large height.

In the semiconductor device described above, the interconnects 221b are directly connected to the corresponding underlying metal interconnects 102. Therefore, the resistance of the interconnects 221b can be further reduced compared with that in the example embodiment shown in FIG. 5. Also, as in the fabrication method of the example embodiment, the fabrication method of this variation can be carried out without increasing the number of steps compared with the general dual damascene process. Thus, using this method, a semiconductor device having a desired interconnect structure can be implemented without increasing the fabrication cost and the time required for the fabrication process.

The methods for fabricating a semiconductor device of the embodiment of the present invention and the variation thereof described above can be applied to semiconductor devices having multilayer metal interconnects as a whole.

What is claimed is:

1. A method for fabricating a semiconductor device, comprising the steps of:
forming an insulating film over a semiconductor substrate;
forming a mask material film on the insulating film and then forming a mask pattern having a first trench formation opening and a second trench formation opening from the mask material film;
forming, on the mask material film, a resist pattern having a third trench formation opening that exposes the first trench formation opening and covering the second trench formation opening;
forming a first trench in a position in the insulating film coinciding with the third trench formation opening using the resist pattern and the mask pattern; and
after removing the resist pattern, forming a second trench in a position in the insulating film coinciding with the second trench formation opening using the mask pattern.

2. The method of claim 1, wherein
in the step of forming a second trench, the first trench is further dug to be deeper than the second trench.

3. The method of claim 1, wherein
the widths of the first trench and the second trench are substantially the same.

4. The method of claim 1, wherein
the width of the third trench formation opening is equal to or larger than the width of the first trench formation opening.

5. The method of claim 1, wherein
the insulating film formed over the semiconductor substrate includes a lower insulating film and an upper insulating film formed on the lower insulating film, and
the method further comprises the step of:
removing the upper insulating film after formation of the second trench.

6. The method of claim 1, wherein
the mask pattern further has a fourth trench formation opening,
the resist pattern further has a contact hole formation opening at least partly exposing the fourth trench formation opening,
in the step of forming a first trench, a contact hole is formed in a position in the insulating film coinciding with an overlap between the fourth trench formation opening and the contact hole formation opening, and
in the step of forming a second trench, a third trench having a bottom at which the contact hole is open is further formed in a position in the insulating film coinciding with the fourth trench formation opening.

7. The method of claim 6, wherein
in the step of forming a first trench, an etching rate of the insulating film for formation of the contact hole is higher than an etching rate of the insulating film for formation of the first trench.

8. The method of claim 6, wherein
in the step of forming a first trench, an etching rate of the insulating film for formation of the contact hole is substantially the same as an etching rate of the insulating film for formation of the first trench.

9. The method of claim 8, wherein
a lower interconnect is formed in a region between the semiconductor substrate and the insulating film, and
in the step of forming a second trench, the first trench reaches a top surface of the lower interconnect.

10. The method of claim 1, wherein
the mask material film is comprised of a material selected from the group consisting of TiN, Ti, Ta, TaN, and SiC.

11. A method for fabricating a semiconductor device, comprising the steps of:
forming an insulating film over a semiconductor substrate;
forming a mask material film on the insulating film and then forming a mask pattern having a first trench formation opening and a second trench formation opening from the mask material film;
forming, on the mask material film, a resist pattern having a third trench formation opening that exposes the first trench formation opening and a contact hole formation opening that exposes part of the second trench formation opening;
forming a first trench in a position in the insulating film coinciding with the third trench formation opening, and also forming a contact hole in a position in the insulating film coinciding with the contact hole formation opening, using the resist pattern and the mask pattern; and
after removing the resist pattern, forming a second trench having a bottom at which the contact hole is open in a position in the insulating film coinciding with the second trench formation opening using the mask pattern.

12. The method of claim 11, wherein
in the step of forming a second trench, the first trench is further dug to be deeper than the second trench.

13. The method of claim 11, wherein
a portion of an inner wall of the second trench and a portion of an inner wall of the contact hole are flush with each other at a position coinciding with an edge of the second trench formation opening.

14. The method of claim 11, wherein
in the step of forming a first trench and a contact hole, an etching rate of the insulating film for formation of the contact hole is equal to or higher than an etching rate of the insulating film for formation of the first trench.

15. The method of claim 11, wherein
the insulating film formed on the semiconductor substrate includes a lower insulating film and an upper insulating film formed on the lower insulating film, and
the method further comprises the step of:
removing the upper insulating film after formation of the second trench.

16. The method of claim 11, further comprising the step of:
after formation of the second trench, forming a contact with which the contact hole is filled, a first interconnect with which the first trench is filled, and a second interconnect with which the second trench is filled, the second interconnect being connected to the contact.

17. The method of claim 1, wherein
the first trench is formed in a region driven with a higher voltage than a region where the second trench is formed.

18. A semiconductor device comprising:
a first insulating film formed over a semiconductor substrate;
a first interconnect formed in the first insulating film;
a second interconnect formed in the first insulating film, the second interconnect being larger in height than the first interconnect; and
a contact formed in the first insulating film to be connected to the first interconnect, wherein
the first interconnect, the second interconnect, and the contact are each comprised of a conductive barrier film and a metal film formed on the barrier film, and
no barrier film is formed at a boundary between the first interconnect and the contact.

19. The semiconductor device of claim 18, further comprising:
a third interconnect formed in the first insulating film, the third interconnect having a width and height approximately equal to the first interconnect.

20. The semiconductor device of claim 18, further comprising:
a second insulating film formed between the semiconductor substrate and the first insulating film; and
a lower interconnect formed in the second insulating film, wherein
the second interconnect is directly connected to the lower interconnect.

21. A semiconductor device comprising:
a first insulating film formed over a semiconductor substrate;
a first interconnect formed in the first insulating film;
a second interconnect formed in the first insulating film, the second interconnect being larger in height than the first interconnect;
a second insulating film formed between the semiconductor substrate and the first insulating film; and
a lower interconnect formed in the second insulating film,
wherein
the second interconnect is directly connected to the lower interconnect.
